(19) United States
(12) Patent Application Publication
(10) Pub. No.: US 2022/0165712 A1
(43) Pub. Date: May 26, 2022

(54) POWER MODULE

(71) Applicant: DENSO CORPORATION, Kariya-city (JP)

(72) Inventors: TETSUYA MATSUOKA, Kariya-city (JP); MITSUNORI KIMURA, Kariya-city (JP); KAZUTOSHI SHIOMI, Kariya-city (JP)

(21) Appl. No.: 17/666,676

(22) Filed: Feb. 8, 2022

Related U.S. Application Data
(63) Continuation of application No. PCT/JP2020/031963, filed on Aug. 25, 2020.

(30) Foreign Application Priority Data
Sep. 4, 2019 (JP) 2019-161494

(51) Int. Cl. H01L 25/07; H01L 23/495; H02M 7/537

(52) U.S. Cl. CPC H01L 25/072; H02M 7/537; H01L 23/49562; H01L 23/49524

(57) ABSTRACT

A power module includes three switching elements including a third switching element, a second switching element, and a third switching element. Each of the switching elements includes two positive electrode terminals including a third positive electrode terminal and a second positive electrode terminal, which are connected to a drain electrode. Each of the switching elements includes one negative electrode terminal including a negative electrode terminal connected to a source electrode. In the power module, a total number of the positive electrode terminals and the negative electrode terminals is three.

### CROSS REFERENCE TO RELATED APPLICATION

The present application is a continuation application of International Patent Application No. PCT/JP2020/031963 filed on Aug. 25, 2020, which designated the U.S. and claims the benefit of priority from Japanese Patent Application No. 2019-161494 filed on Sep. 4, 2019. The entire disclosures of all of the above applications are incorporated herein by reference.

### TECHNICAL FIELD

The present disclosure relates to a power module.

### BACKGROUND

A semiconductor module including transistor chips is known.

### SUMMARY

According to an aspect of the present disclosure, a power module includes three or more switching elements that are connected in parallel with each other.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a plan view showing a schematic configuration of a power module according to a first embodiment.

FIG. 2 is a cross-sectional view taken along a line II-II in FIG. 1.

FIG. 3 is a circuit diagram showing a schematic configuration of an inverter according to the first embodiment.

FIG. 4 is a plan view showing a schematic configuration of a power module according to a second embodiment.

FIG. 5 is a plan view showing a schematic configuration of the power module according to a second embodiment.

FIG. 6 is a chart showing a relationship between distances of elements according to the second embodiment.

FIG. 7 is a cross-sectional view showing a schematic configuration of a power module according to a third embodiment.

FIG. 8 is a cross-sectional view showing a schematic configuration of a power module according to a fourth embodiment.

FIG. 9 is a plan view showing a schematic configuration of a power module according to a fifth embodiment.

FIG. 10 is a plan view showing a schematic configuration of a power module according to a sixth embodiment.

FIG. 11 is a plan view showing a schematic configuration of a power module according to a seventh embodiment.

FIG. 12 is a plan view showing a schematic configuration of a power module according to an eighth embodiment.

FIG. 13 is a plan view showing a schematic configuration of a power module according to a ninth embodiment.

FIG. 14 is a plan view showing a schematic configuration of a power module according to a tenth embodiment.

FIG. 15 is a plan view showing a schematic configuration of a power module according to an eleventh embodiment.

FIG. 16 is a circuit diagram showing a schematic configuration of an inverter according to the eleventh embodiment.

### DETAILED DESCRIPTION

Hereinafter, examples of the present disclosure will be described.

A semiconductor module according to an example of the present disclosure includes a pair of metal plates and two transistor chips. The transistor chip is sandwiched between a pair of metal plates and is sealed in a resin package. An emitter electrode of the transistor chip conducts with one of the metal plates. The semiconductor module has two collector terminals extending from the other metal plate and one emitter terminal extending from the one metal plate. The emitter terminal extends outward from a lateral side surface of the package between the two collector terminals. The emitter terminal extends from the one metal plate at an equal distance from the emitter electrode of the two transistor chips.

In addition to consideration of a gate oscillation, there may be a room to consider a configuration in which three or more elements, which are smaller and are better in yield.

According to an example of the present disclosure, a power module includes three or more switching elements that are connected in parallel with each other, a positive electrode terminal that is connected to a positive electrode of each of the switching elements, a negative electrode terminal that is connected to a negative electrode of each of the switching elements, and a total number of the positive electrode terminals and negative electrode terminals is three or more. In this configuration, three or more switching elements are connected in parallel, and therefore, a yield thereof can be improved.

Further according to an example of the present disclosure, a sum of a positive electrode side distance, which is a distance between a center of the switching element and a positive electrode terminal closest to the switching element, and a negative electrode side distance, which is a distance between a center of the switching element and a negative electrode terminal closest to the switching element, is equal for each of the switching elements.

In this way, the present disclosure enables to suppress a current imbalance for each of the switching elements.

Hereinafter, multiple embodiments of the present disclosure will be described with reference to the drawings. In each embodiment, portions corresponding to those described in the preceding embodiment are denoted by the same reference numerals, and redundant descriptions will be omitted in some cases. In each embodiment, in a case where only a part of the configuration is described, another preceding embodiment can be referenced to and applied to the other parts of the configuration. Hereinafter, three directions perpendicular to each other are denoted as an X direction, a Y direction, and a Z direction.

### First Embodiment

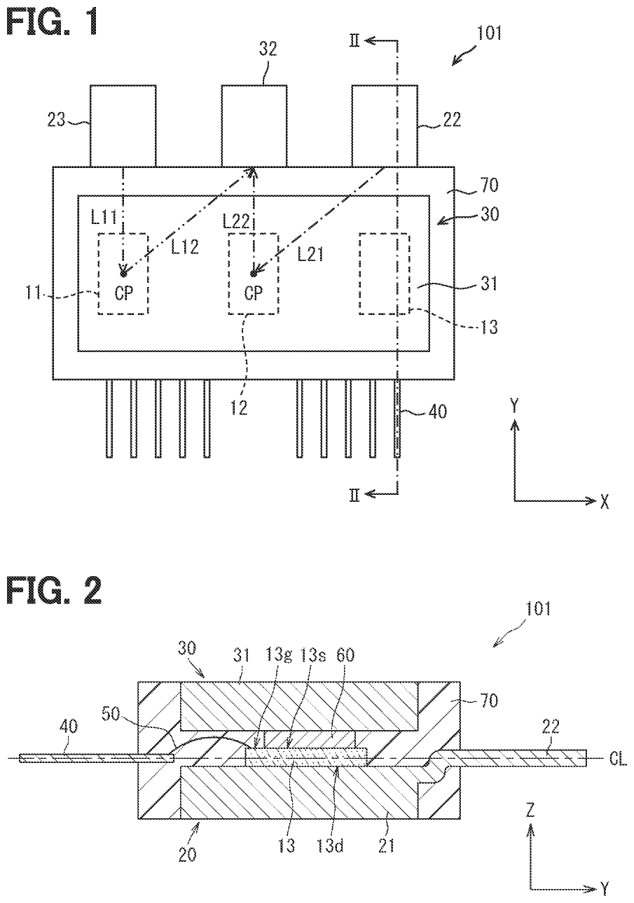

A power module 101 of the present embodiment will be described with reference to FIGS. 1, 2, and 3. The power module 101 mainly includes a first switching element 11, a second switching element 12, a third switching element 13, a first terminal member 20, and a second terminal member 30. Further, the power module 101 may include signal terminals 40, a wire 50, a terminal 60, a sealing portion 70, and the like.

As shown in FIG. 1, the switching elements 11 to 13 are arranged side by side in one direction. Further, the switching elements 11 to 13 are arranged in the order of the first switching element 11, the second switching element 12, and the third switching element 13. Herein, an example in which the first switching element 11, the second switching element 12, and the third switching element 13 are arranged side by side in the X direction is adopted.

In this embodiment, a MOSFET is adopted as an example of each of the switching elements 11 to 13. However, the present disclosure is not limited to this, and IGBTs, RC-IGBTs, and the like may be adopted for the switching elements 11 to 13. Further, as the switching elements 11 to 13, a switching element having Si as a main component, a switching element having SiC as a main component, a switching element having GaN as a main component, and the like may be adopted. Each of the switching elements 11 to 13 is a semiconductor switching element.

The three switching elements 11 to 13 have a similar configuration. Therefore, herein, the third switching element 13 will be described as a representative example. The switching elements 11 to 13 are placed at the same position in a height direction (Z direction).

As shown in FIG. 2, the third switching element 13 has a gate electrode 13g, a drain electrode 13d, and a source electrode 13s. The third switching element 13 is formed with the gate electrode 13g and the source electrode 13s on one surface thereof and is formed with the drain electrode 13d on the opposite surface from the one surface. The third switching element 13 has a hexahedral structure and is in a rectangular planar shape.

As shown in FIG. 2, the switching elements 11 to 13 are arranged between the first terminal member 20 and the second terminal member 30, which will be described later. In the third switching element 13, the gate electrode 13g and the source electrode 13s are arranged so as to face the second terminal member 30, and the drain electrode 13d is arranged so as to face the first terminal member 20.

The source electrode 13s is arranged to face the second terminal member 30 via the terminal 60. The source electrode 13s is connected to the terminal 60 via a conductive connecting member. Further, the terminal 60 is connected to the second terminal member 30 via a conductive connecting member. In this way, the source electrode 13s is electrically connected to the second terminal member 30 via the terminal 60. On the other hand, the drain electrode 13d is connected to the first terminal member 20 via a conductive connecting member. For the conductive connecting member, for example, solder or the like may be adopted.

Therefore, in the three switching elements 11 to 13, the source electrodes are electrically connected with each other via the second terminal member 30, and the drain electrodes are electrically connected with each other via the first terminal member 20. In this way, the three switching elements 11 to 13 are connected in parallel with each other.

The gate electrode 13g is electrically connected to the signal terminal 40 via the wire 50. The terminal 60 is provided to prevent the wire 50 connected to the gate electrode 13g from coming into contact with the second terminal member 30. The terminal 60, which is formed of a metal such as Al or Cu as a main component, or the terminal 60 formed of an alloy may be adopted.

The power module 101 is also arranged and connected to the first switching element 11 and the second switching element 12 in a similar manner to the third switching element 13.

As shown in FIGS. 1 and 2, the first terminal member 20 has a positive electrode side heat sink 21, a first positive electrode terminal 22, a second positive electrode terminal 23, and the like. The first terminal member 20 includes the positive electrode side heat sink 21, the first positive electrode terminal 22, and the second positive electrode terminal 23 as an integral body. The first terminal member 20, which is formed of a metal such as Al or Cu as a main component, or the first terminal member 20 formed of an alloy may be adopted.

The positive electrode side heat sink 21 is a portion facing each of the switching elements 11 to 13. The positive electrode side heat sink 21 has a function of cooling each of the switching elements 11 to 13. That is, heat generated from each of the switching elements 11 to 13 is transferred to the positive electrode side heat sink 21 by operating. Then, the positive electrode side heat sink 21 cools each of the switching elements 11 to 13 by radiating the heat generated from the switching elements 11 to 13 to the outside of the sealing portion 70. The positive electrode side heat sink 21 is provided to be thicker than the positive electrode terminals 22 and 23 in order to cool the switching elements 11 to 13. The thickness is the width in the Z direction.

The first positive electrode terminal 22 and the second positive electrode terminal 23 correspond to the positive electrode terminals. The first positive electrode terminal 22 and the second positive electrode terminal 23 are connected to drain electrodes (positive electrodes) of the switching elements 11 to 13. The first positive electrode terminal 22 and the second positive electrode terminal 23 are provided at the same positions in the height direction. Further, as shown in FIG. 2, the positive electrode terminals 22 and 23 are provided at the same positions in the height direction as the switching elements 11 to 13. Herein, an example, in which the positive electrode terminals 22 and 23 and the switching elements 11 to 13 are arranged on the center line CL in the height direction of the power module 101, is adopted.

The first positive electrode terminal 22 and the second positive electrode terminal 23 are external connection terminals for electrically connecting the power module 101 with an external device. The first positive electrode terminal 22 and the second positive electrode terminal 23 are provided so as to project from a side wall of the positive electrode side heat sink 21. Further, the first positive electrode terminal 22 and the second positive electrode terminal 23 are provided so as to project in the Z direction and are arranged side by side in the X direction. As shown in FIG. 1, the first positive electrode terminal 22 and the second positive electrode terminal 23 are provided so as to be separated from each other so that the negative electrode terminal 32 can be arranged between the terminals. As described above, the first terminal member 20 has a function as a positive electrode terminal and a function for cooling the switching elements 11 to 13.

The first terminal member 20 may have configuration in which the positive electrode side heat sink 21, the first positive electrode terminal 22, and the second positive electrode terminal 23 are separately provided. In this case, the positive electrode side heat sink 21 is connected to the first positive electrode terminal 22 and the second positive electrode terminal 23 via a conductive connecting member such as solder.

As shown in FIGS. 1 and 2, the second terminal member 30 has a negative electrode side heat sink 31, a negative electrode terminal 32, and the like. The second terminal member 30 includes the negative electrode side heat sink 31 and the negative electrode terminal 32 as an integral body. The second terminal member 30, which is formed of a metal such as Al or Cu as a main component, or the second terminal member 30 formed of an alloy may be adopted.

The negative electrode side heat sink 31 has a similar configuration and a similar function to the positive electrode side heat sink 21. The negative electrode terminal 32 corresponds to a negative electrode terminal. The negative electrode terminal 32 is connected to the source electrode (negative electrode) of each of the switching elements 11 to 13. The negative electrode terminal 32 has a similar configuration and a similar function to the first positive electrode terminal 22 and the second positive electrode terminal 23. As shown in FIG. 1, the negative electrode terminal 32 is arranged between the first positive electrode terminal 22 and the second positive electrode terminal 23. Therefore, the second terminal member 30 has a function as the negative electrode terminal and a function for cooling the switching elements 11 to 13. The second terminal member 30 is provided with only one negative electrode terminal 32 protruding from the negative electrode side heat sink 31.

Further, the negative electrode terminal 32 is provided at the same position in the height direction as the positive electrode terminals 22 and 23.

The second terminal member 30 may have a configuration in which the negative electrode side heat sink 31 and the negative electrode terminal 32 are separately provided. In this case, the negative electrode side heat sink 31 is connected to the negative electrode terminal 32 via a conductive connecting member such as solder.

As described above, in the power module 101, the total number of the positive electrode terminals 22 and 23 and the negative electrode terminals 32 is three. That is, the power module 101 includes two positive electrode terminals 22 and 23 and one negative electrode terminal 32. It is noted that, the present disclosure is not limited to this, and the total number of the positive electrode terminals and the negative electrode terminals may be three or more. The power module 101 includes three switching elements 11 to 13 connected in parallel, and therefore, the yield thereof can be improved. That is, the power module 101 enables to improve the yield as compared with a configuration which uses three or more smaller elements having a good yield.

A signal terminal 40, which is formed of a metal such as Al or Cu as a main component, or the signal terminal 40 formed of an alloy may be adopted. A plurality of the signal terminals 40 are provided and are arranged side by side in the X direction. The signal terminals 40 include a gate terminal connected with a gate terminal of corresponding one of the switching elements 11 to 13 via the wire 50. In a configuration where the switching elements 11 to 13 are provided with a temperature sensor, the signal terminals 40 include a temperature detection terminal electrically connected to the temperature sensor. The signal terminals 40 are not limited to the gate terminal and the temperature detection terminal and may include another terminal.

The sealing portion 70 is mainly composed of an electrically insulating resin such as an epoxy resin. As shown in FIG. 2, the sealing portion 70 is in contact with and covers the switching elements 11 to 13, a part of the first terminal member 20, and a part of the second terminal member 30. Further, the sealing portion 70 is in contact with and covers the wire 50, the terminal 60, and a part of the signal terminals 40. Further, the sealing portion 70 also covers a connecting portion between components of the power module 101.

In the power module 101, a part of the positive electrode terminals 22 and 23, a part of the negative electrode terminal 32, and a part of the signal terminals 40 protrude from the sealing portion 70. More specifically, the positive electrode terminals 22 and 23 and the negative electrode terminal 32 project from one side wall of the sealing portion 70. On the other hand, the signal terminals 40 protrude from the other side wall of the sealing portion 70. That is, the signal terminals 40 protrude from the side wall of the sealing portion 70, which is different from that from which the positive electrode terminals 22 and 23, and the like protrude. Further, in other words, the signal terminals 40 are provided on the side opposite to the positive electrode terminals 22 and 23 and the negative electrode terminal 32 with respect to the switching elements 11 to 13. In this configuration, the signal terminals 40 in the power module 101 are less likely to receive noise from the positive electrode terminals 22, 23 and the negative electrode terminals 32.

Further, in the first terminal member 20, a surface of the positive electrode side heat sink 21 opposite from a surface of the positive electrode side heat sink 21, which faces the switching elements 11 to 13, is exposed from the sealing portion 70. Similarly, in the second terminal member 30, a surface of the negative electrode side heat sink 31 opposite from a surface of the negative electrode side heat sink 31, which faces the switching elements 11 to 13, is exposed from the sealing portion 70. In the present configuration, the power module 101 sis enabled to easily dissipate the heat of the switching elements 11 to 13 from the positive electrode side heat sink 21 and the negative electrode side heat sink 31.

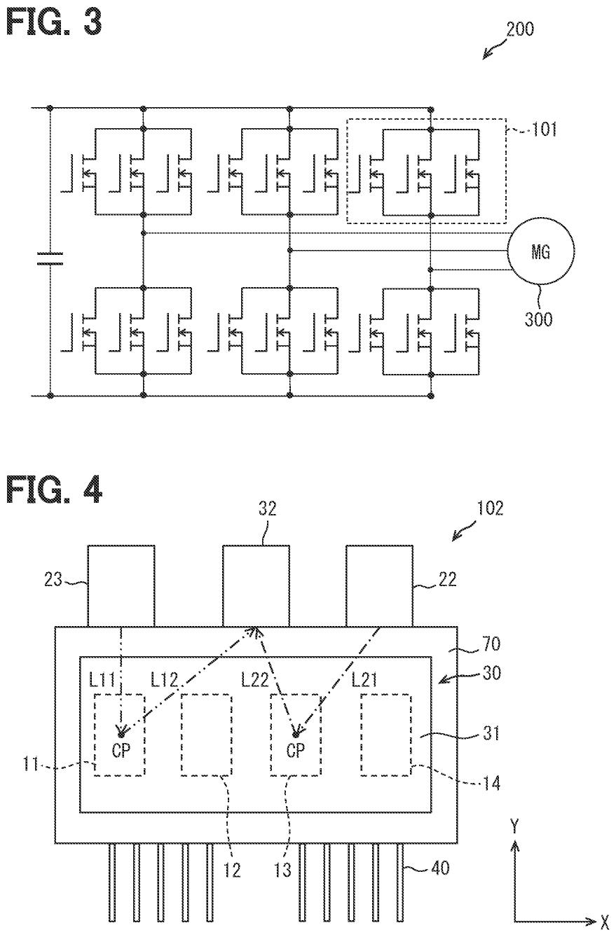

As shown in FIG. 3, the power module 101 may be applied to an inverter 200. The inverter 200 is a circuit for driving and controlling a motor generator 300. The power module 101 includes six power modules 101. It is noted that, the power module 101 is not limited to this, and may be applied to a converter.

In the power module 101 configured in this way, the distances between the switching elements 11 to 13 and the positive electrode terminals 22 and 23 and the negative electrode terminals 32 are specified. In short, the power module 101 is specified so that the total of the positive electrode side distances L11 and L21 and the total of the negative electrode side distances L12 and L22 are equal to each other for each of the switching elements 11 to 13. The positive electrode terminals 22 and 23 and the negative electrode terminal 32 are, in other words, main circuit terminals.

The positive electrode side distance L11 is a distance between a center point CP of the first switching element 11 and the positive electrode terminal (second positive electrode terminal 23) closest to the first switching element 11. The negative electrode side distance L12 is a distance between the center point CP of the first switching element 11 and the negative electrode terminal (negative electrode terminal 32) closest to the first switching element 11.

A starting point of these distances on the side of the switching element 11 to 13 is the center point CP of each of the switching elements 11 to 13. On the other hand, a starting point of the distances on the side of the terminal is a boundary surface of each of the terminals 22, 23, 32 at a boundary between the terminal 22, 23, 32 and the sealing portion 70. Therefore, for example, the positive electrode side distance L11 is, in other words, a distance between the center point CP of the first switching element 11 and the boundary surface of the second positive electrode terminal 23 at a boundary between the second positive electrode terminal 23 and the sealing portion 70. Further, the positive electrode side distance L11 is, in other words, a distance between the center point CP of the first switching element 11 and the boundary between the second positive electrode terminal 23 and the sealing portion 70. The boundary surface corresponds to a cross section of the terminal 22, 23, 32 in the thickness direction (Z direction) at the boundary between the terminal 22, 23, 32 and the sealing portion 70.

The positive electrode side distance L21 is a distance between the center point CP of the second switching element 12 and the positive electrode terminal (first positive electrode terminal 22) closest to the second switching element 12. The negative electrode side distance L22 is a distance between the center point CP of the second switching element 12 and the negative electrode terminal (negative electrode terminal 32) closest to the second switching element 12.

The positive electrode side distance of the third switching element 13 is a distance between the center point CP of the third switching element 13 and the first positive electrode terminal 22 closest to the third switching element 13. The negative electrode side distance of the third switching element 13 is a distance between the center point CP of the third switching element 13 and the negative electrode terminal 32 closest to the third switching element 13.

The total of the positive electrode side distance L11 and the negative electrode side distance L12 of the first switching element 11 is equal to the total of the positive electrode side distance L21 and the negative electrode side distance L22 of the second switching element 12. Further, the total of the positive electrode side distance and the negative electrode side distance of the third switching element 13 is equal to the total of the positive electrode side distance L21 and the negative electrode side distance L22 of the second switching element 12. In this way, in the power module 101, the wirings of the switching elements 11 to 13 with the main circuit terminals are in equal-length wirings.

Therefore, the power module 101 enables to suppress the imbalance of the current flowing through each of the switching elements 11 to 13. Further, the power module 101 has a plurality of main circuit terminals, which facilitates the equal-length wirings. Further, the power module 101 enables to suppress the current imbalance in consideration of manufacturing variation by setting the starting point on the terminal side as the boundary surface of the terminal 22, 23, 32 at the boundary between the terminal 22, 23, 32 and the sealing portion 70.

Further, it may be preferable that the starting point on the terminal side is the center of the boundary surface between the terminals 22, 23, 32 and the sealing portion 70. A current distribution exists at the boundary surface of the terminals 22, 23, and 32. It is noted that, the terminals 22, 23, and 32 are most likely to conduct electricity at the center of the boundary surface. Therefore, the power module 101 produces an enhanced effect of suppressing the current imbalance.

As described above, in the power module 101, the positive electrode terminals 22 and 23 and the negative electrode terminals 32 are arranged side by side in the one direction. Further, in the power module 101, the switching elements 11 to 13 are arranged in a row along an arrangement direction in which the positive electrode terminals 22 and 23 and the negative electrode terminals 32 are arranged. Therefore, the configuration enables in the power module 101 to project the signal terminals 40 from the sealing portion 70 to the outside. Further, the configuration facilitates the wirings with the same length in the power module 101.

In the present embodiment, the power module 101 having three switching elements 11 to 13 is adopted. It is noted that, the present disclosure is not limited to this, and various power modules having three or more switching elements may be adopted.

As described above, an embodiment of the present disclosure has been described. However, the present disclosure is not limited to the embodiment described above, and various modifications are possible within the scope of the present disclosure without departing from the spirit of the present disclosure. Hereinafter, as other forms of the present disclosure, second to eleventh embodiments will be described. The above-described embodiment and the second to eleventh embodiments may be implemented independently or in combination as appropriate. The present disclosure can be performed by various combinations without being limited to the combination illustrated in the embodiment.

### Second Embodiment

A power module 102 of the present embodiment will be described with reference to FIGS. 4, 5, and 6. Here, mainly, the configurations of the power module 102 different from the power module 101 will be described. The power module 102 differs from the power module 101 in the number of switching elements 11 to 14. In the power module 102, the same components as those of the power module 101 are given the same reference numerals as those of the power module 101.

As shown in FIG. 4, the power module 102 has a fourth switching element 14 in addition to the switching elements 11 to 13. In the power module 102, similarly to the power module 101, the wirings of the switching elements 11 to 14 with the main circuit terminals are in equal-length wirings. Therefore, the power module 102 enables to produce a similar effect to the effect of the power module 101. The configuration in which the switching elements 11 to 13 are four may be applied to the other embodiments.

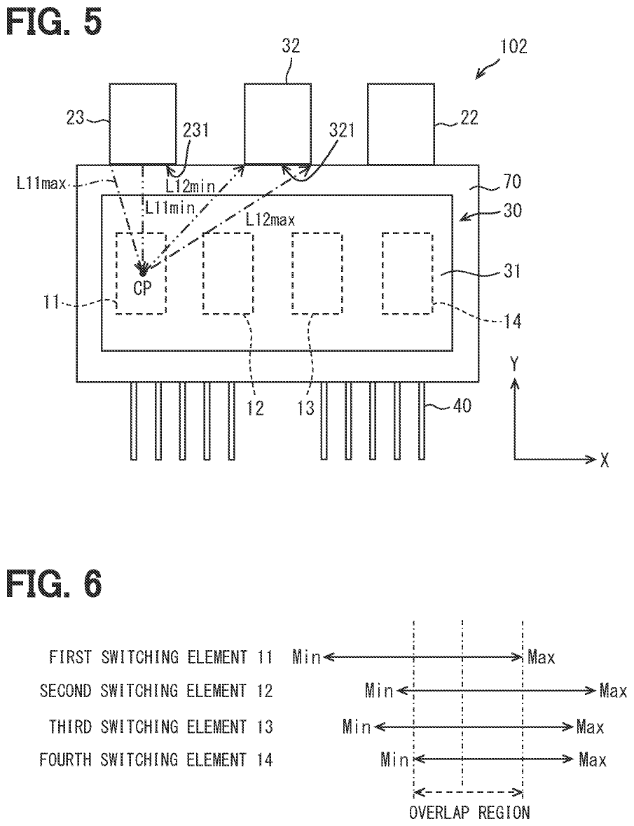

Further, as shown in FIG. 5, in the present disclosure, the difference between the shortest distance and the longest distance of each of the switching elements 11 to 14 may be used such that the wirings of the switching elements 11 to 14 with the main circuit terminals become the equal-length wirings.

The reference numeral L11min in FIG. 5 is the shortest distance between the first switching element 11 and the second positive electrode terminal 23, which is the positive electrode terminal closest to the first switching element 11. The reference numeral L11max is the longest distance between the first switching element 11 and the second positive electrode terminal 23. The reference numeral L12min is the shortest distance between the first switching element 11 and the negative electrode terminal 32, which is the negative electrode terminal closest to the first switching element 11. The reference numeral L12max is the longest distance between the first switching element 11 and the negative electrode terminal 32. The method of measurement of the shortest distance and the longest distance may be similarly applied to the other switching elements 12 to 14.

The reference numeral 231 is a boundary surface (first boundary surface) of the second positive electrode terminal 23 at the boundary from the sealing portion 70. On the other hand, the reference numeral 321 is a boundary surface (second boundary surface) of the second positive electrode terminal 23 at the boundary from the sealing portion 70.

As shown in FIG. 6, in the power module 102, there is a region (overlapping region) in which the difference between the shortest distance and the longest distance for each of the switching elements 11 to 14 is overlapped in all the switching elements 11 to 14. That is, the power module 102 is configured so that an overlapping region exists. The power module 102 has the overlapping region, and therefore, it may be considered that the wirings of the switching elements 11 to 14 with the main circuit terminals are equal-length wirings. Also in this perspective, the power module 102 enables to produce a similar effect to the effect of the power module 101.

### Third Embodiment

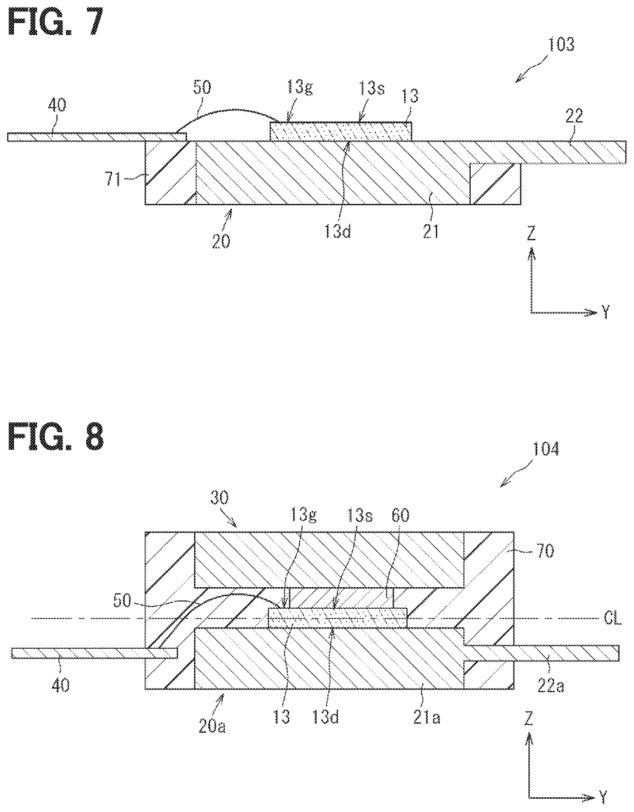

A power module 103 of the third embodiment will be described with reference to FIG. 7. Here, mainly, the configurations of the power module 103 different from the power module 101 will be described. The power module 103 differs from the power module 101 in that the switching elements 11 to 13 dissipate heat on one side. FIG. 7 is a cross-sectional view corresponding to FIG. 2. In the power module 103, the same components as those of the power module 101 are given the same reference numerals as those of the power module 101.

As shown in FIG. 7, the power module 103 is not provided with the second terminal member 30 and the terminal 60. A sealing portion 71 does not seal the switching elements 11 to 13, the second terminal member 30, and the terminal 60. Therefore, each of the switching elements 11 to 13 mainly dissipates heat from the positive electrode side heat sink 21. In each of the switching elements 11 to 13, the source electrode 13s and the negative electrode terminal 32 are electrically connected to each other via a wire or the like.

Therefore, the power module 103 enables to produce a similar effect to the effect of the power module 101. The configuration in which the switching elements 11 to 13 dissipate heat on one side may be applied to the other embodiments.

### Fourth Embodiment

A power module 104 of the fourth embodiment will be described with reference to FIG. 8. Here, mainly, the configurations of the power module 104 different from the power module 101 will be described. The power module 104 is different from the power module 101 in the configuration of a first terminal member 20a. FIG. 8 is a cross-sectional view corresponding to FIG. 2. In the power module 104, the same components as those of the power module 101 are given the same reference numerals as those of the power module 101.

As shown in FIG. 8, the power module 104 includes the first terminal member 20a. Similarly to the first terminal member 20, the first terminal member 20a includes a positive electrode side heat sink 21a and a first positive electrode terminal 22a. Further, the first terminal member 20a includes a second positive electrode terminal 23 similarly to the first terminal member 20. The position of the second positive electrode terminal 23 in the Z direction is the same as that of the first positive electrode terminal 22a.

The first terminal member 20a is different from that of the first terminal member 20 in the position of the first positive electrode terminal 22a with respect to the switching elements 11 to 13. The first positive electrode terminal 22a is different from the switching elements 11 to 13 in the position in the height direction. The first positive electrode terminal 22a is placed at a position farther from the switching elements 11 to 13 than a mounting surface of the positive electrode side heat sink 21a, on which the switching elements 11 to 13 are mounted, in the Z direction. Therefore, the first positive electrode terminal 22a is, in other words, arranged below the center line CL. Herein, the direction to the second terminal member 30 relative to the center line CL is an upper side, and the direction to the first terminal member 20a relative to the center line a lower side.

Therefore, the power module 104 enables to produce a similar effect to the effect of the power module 101. The configuration of the first terminal member 20a may be applied to the other embodiments.

### Fifth Embodiment

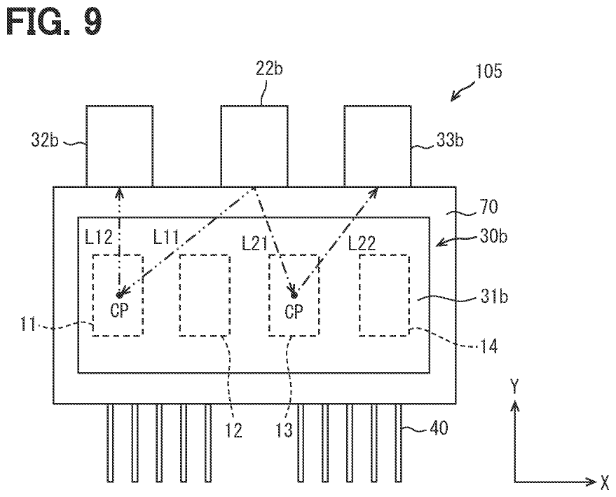

A power module 105 of the fifth embodiment will be described with reference to FIG. 9. Here, mainly, the configurations of the power module 105 different from the power module 102 will be described. The power module 105 differs from the power module 102 in the number of a positive electrode terminals 22b and the negative electrode terminals 32b and 33b. In the power module 105, the same components as those of the power module 102 are given the same reference numerals as those of the power module 102.

As shown in FIG. 9, the power module 105 includes a second terminal member 30b. The second terminal member 30b includes a negative electrode side heat sink 31b, a first negative electrode terminal 32b, and a second negative electrode terminal 33b. Further, the first terminal member includes one positive electrode terminal 22b and a positive electrode side heat sink. The positive electrode terminal 22b is connected to the positive electrode side heat sink. Therefore, the second terminal member 30b has a similar configuration to that of the first terminal member 20. The first terminal member has a similar configuration to that of the second terminal member 30. As described above, the power module 105 includes the one positive electrode terminal 22b, the two negative electrode terminal 32b and the second negative electrode terminal 33b.

The terminals 22b, 32b, 33b are arranged side by side in the X direction. Further, the terminals 22b, 32b, 33b are at the same position as the switching elements 11 to 13 in the height direction.

The power module 105 enables to produce a similar effect to the effect of the power module 102. The configuration of the positive electrode terminal 22b and the negative electrode terminals 32b, 33b may be applied to the other embodiments.

### Sixth Embodiment

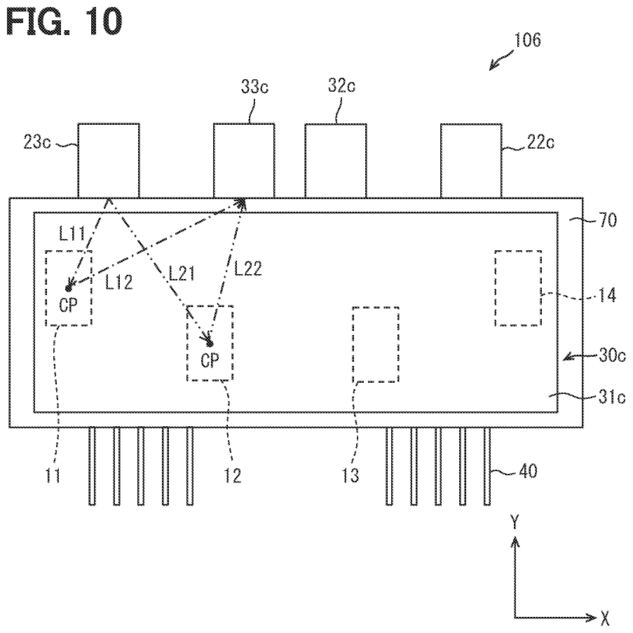

A power module 106 of the sixth embodiment will be described with reference to FIG. 10. Here, mainly, the configurations of the power module 106 different from the power module 102 will be described. The power module 106 differs from the power module 102 in the number of the negative electrode terminals 32c and 33c and the arrangement of the switching elements 11 to 14. In the power module 106, the same components as those of the power module 102 are given the same reference numerals as those of the power module 102.

As shown in FIG. 10, the power module 106 includes a second terminal member 30c. The second terminal member 30c includes a negative electrode side heat sink 31c, a first negative electrode terminal 32c, and a second negative electrode terminal 33c. Although the second terminal member 30c has a similar configuration to the second terminal member 30, the number of the negative electrode terminals is larger than that of the second terminal member 30. Further, similarly to the first terminal member 20, the first terminal member includes a first positive electrode terminal 22c, a second positive electrode terminal 23c, and a positive electrode side heat sink connected to the first positive electrode terminal 22c and the second positive electrode terminal 23c.

The terminals 23c, 33c, 32c, and 22c are arranged side by side in the X direction. The positions of the terminals 23c, 33c, 32c, and 22c in the height direction are the same as those of the switching elements 11 to 14.

As for the switching elements 11 to 14, the first switching element 11 and the fourth switching element 14 are arranged side by side in the X direction, and the second switching element 12 and the third switching element 13 are arranged side by side in the X direction. The second switching element 12 and the third switching element 13 are arranged between the first switching element 11 and the fourth switching element 14. Further, the second switching element 12 and the third switching element 13 are arranged at positions shifted from the first switching element 11 and the fourth switching element 14 toward the signal terminal 40. The power module 106 enables to produce a similar effect to the effect of the power module 102. The configurations of the negative electrode terminals 32c and 33c and the arrangement of the switching elements 11 to 14 may be applied to the other embodiments.

### Seventh Embodiment

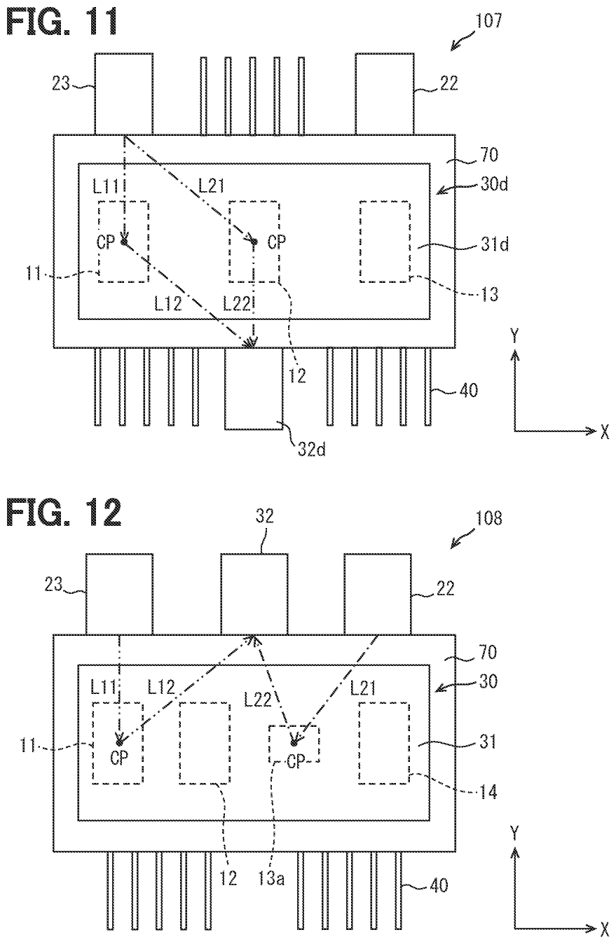

A power module 107 of the seventh embodiment will be described with reference to FIG. 11. Here, mainly, the configurations of the power module 107 different from the power module 101 will be described. A direction, in which the negative electrode terminal 32d of the power module 107 protrudes, is different from that of the power module 101. In the power module 107, the same components as those of the power module 101 are given the same reference numerals as those of the power module 101.

As shown in FIG. 11, the power module 107 includes a second terminal member 30d. The second terminal member 30d includes a negative electrode side heat sink 31d and the negative electrode terminal 32d. The negative electrode terminal 32d is provided on the side opposite to the positive electrode terminals 22 and 23. That is, the power module 107 is provided with the negative electrode terminal 32d and the positive electrode terminals 22 and 23 protruding from the sealing portion 70. In the power module 107, the direction, in which the negative electrode terminals 32d protrudes, is different from the direction, in which the positive electrode terminals 22 and 23 protrude, with respect to the switching elements 11 to 13. The positions of the terminals 22, 23, and 32d in the height direction are the same as those of the switching elements 11 to 14.

The power module 107 enables to produce a similar effect to the effect of the power module 101. The configuration of the negative electrode terminal 32d may be applied to the other embodiments.

### Eighth Embodiment

A power module 108 of the eighth embodiment will be described with reference to FIG. 12. Here, mainly, the configurations of the power module 108 different from the power module 102 will be described. The power module 108 differs from the power module 102 in the configuration of the switching element 13a. In the power module 108, the same components as those of the power module 102 are given the same reference numerals as those of the power module 102.

As shown in FIG. 12, in the power module 108, among the four switching elements 11, 12, 13a, only the third switching element 13a is different from the other switching elements 11, 12, 14 in the element size. The other switching elements 11, 12, and 14 all have the same element size. The third switching element 13a is an element smaller than the first switching element 11. In this configuration, the power module 108 is enhanced in versatility than the power module 102.

The element size represents at least the size in the XY plane. The element size may represent the thickness in the Z direction in addition to the size in the XY plane. Further, the power module 108 may adopt a configuration in which at least one of three or more switching elements has a different element size from those of the other switching elements. Therefore, in the power module 108, for example, the element size of two of the four switching elements may be different from the element size of the other two switching elements.

Further, the third switching element 13a may have a semiconductor configuration different from those of the other switching elements 11, 12, and 14. For example, the other switching elements 11, 12, and 14 are composed of Si as a main component. On the other hand, the third switching element 13a is composed mainly of SiC. It is noted that, the semiconductor configuration is not limited to these combinations. The power module 108 may include a switching element composed of GaN as a main component, a switching element composed of Si as a main component, and the like.

In this way, the power module 108 may also be applied to a hybrid drive such as an IGBT and a MOSFET. That is, the power module 108 may be an IGBT in which the other switching elements 11, 12, and 14 are mainly composed of Si, and the third switching element 13a may be a MOSFET composed mainly of SiC.

Further, the power module 108 may adopt a configuration in which at least one of three or more switching elements has a different semiconductor configuration from those of the other switching elements. Therefore, in the power module 108, for example, the semiconductor configuration of two of the four switching elements may be different from the semiconductor configuration of the other two switching elements.

The power module 108 enables to produce a similar effect to the effect of the power module 102. The configuration in which one switching element 13a is different from other switching elements may be applied to the other embodiments.

### Ninth Embodiment

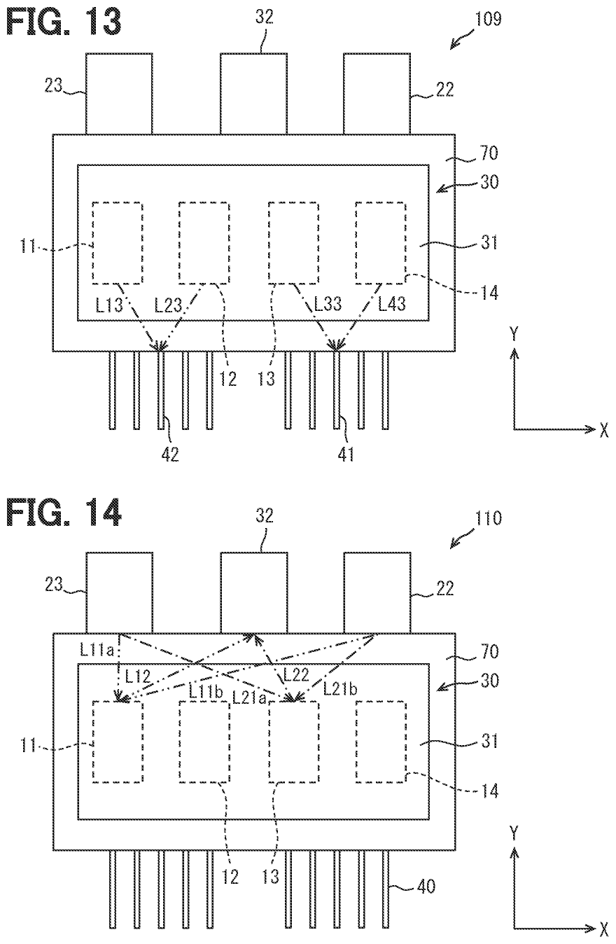

A power module 109 of the ninth embodiment will be described with reference to FIG. 13. Here, mainly, the configurations of the power module 109 different from the power module 102 will be described. The power module 109 differs from the power module 102 in the relationship between the switching elements 11 to 14 and gate terminals 41 and 42. In the power module 109, the same components as those of the power module 102 are given the same reference numerals as those of the power module 102.

As shown in FIG. 13, the power module 109 has two gate terminals 41 and 42. The gate terminals 41 and 42 are a part of the signal terminals. In the first switching element 11 and the second switching element 12, the gate electrodes are electrically connected to the first gate terminals 41, respectively. In the third switching element 13 and the fourth switching element 14, the gate electrodes are electrically connected to the second gate terminals 42, respectively. The power module 109 may have three or more gate terminals.

The reference numeral L13 is a distance between the first switching element 11 and the second gate terminal 42, which is the gate terminal closest to the first switching element 11. The distance L13 is, for example, a distance between the center of a side wall of the switching element 11 on the side of the second gate terminal 42 and the boundary between the second gate terminal 42 and the sealing portion 70. The same applies to the other distances L23 to 43.

The reference numeral L23 is a distance between the second switching element 12 and the second gate terminal 42, which is the gate terminal closest to the second switching element 12. The reference numeral L33 is a distance between the third switching element 13 and the first gate terminal 41, which is the gate terminal closest to the third switching element 13. The reference numeral L43 is a distance between the fourth switching element 14 and the first gate terminal 41, which is the gate terminal closest to the fourth switching element 14. The distance L13, the distance L23, the distance L33, and the distance L43 correspond to a gate distance.

In the power module 109, the distance L13, distance L23, distance L33, and distance L43 are equal to each other. That is, in the power module 109, at least one of the positions of the gate terminals 41 and 42 and the positions of the switching elements 11 to 14 are set so that the distance L13, the distance L23, the distance L33, and the distance L43 are equal to each other.

The power module 109 enables to produce a similar effect to the effect of the power module 102. Further, in the power module 109, the wirings between the switching elements 11 to 14 and the gate terminals 41 and 42 are in the equal length wirings, thereby to enable to further suppress the imbalance of the current flowing through the switching elements 11 to 14. Further, the power module 109 includes the plurality of gate terminals 41 and 42, hereby to enable to facilitate the equal-length wirings for the gate terminals 41 and 42. The relationship between the switching elements 11 to 14 and the gate terminals 41 and 42 may be applied to other embodiments.

### Tenth Embodiment

A power module 110 of the tenth embodiment will be described with reference to FIG. 14. Here, mainly, the configurations of the power module 110 different from the power module 102 will be described. The power module 110 is different from the power module 102 in the relationship between the switching elements 11 to 14 and the terminals 22, 23, 32. In the power module 110, the same components as those of the power module 102 are given the same reference numerals as those of the power module 102.

The reference numeral L11a is a distance between the first switching element 11 and the second positive electrode terminal 23. The reference numeral L11b is a distance between the first switching element 11 and the first positive electrode terminal 22. The reference numeral L12 is a distance between the first switching element 11 and the negative electrode terminal 32.

The reference numeral L21a is a distance between the third switching element 13 and the second positive electrode terminal 23. The reference numeral L21b is a distance between the third switching element 13 and the first positive electrode terminal 22. The reference numeral L22 is a distance between the third switching element 13 and the negative electrode terminal 32.

Herein, the centers of the side walls of the switching elements 11 to 14 on the side of the terminals 22, 23, and 32 are adopted as the starting points on the side of the switching elements 11 to 14, respectively. It is noted that, the present disclosure is not limited to this, and the same starting point as that in the first embodiment may be adopted. On the other hand, the starting points on the side of the terminals 22, 23, and 32 are the same as those in the above embodiments.

In the power module 109, the total of an average of the distances between the switching elements 11 to 14 and the positive electrode terminals 22 and 23 and an average of the distances between the switching elements 11 to 13 and the negative electrode terminal 32 is specified. That is, in the power module 109, the total of the average of the distances between the switching elements 11 to 13 and the positive electrode terminals 22 and 23 and the average of the distances between the switching elements 11 to 13 and the negative electrode terminal 32 is specified to be equal for the switching elements 11 to 14.

For example, the total of the distance for the first switching element 11 is the total of the average of the distance L11a and the distance L11b and the average of the distance L12. The total distance for the third switching element 13 is the total of the average of the distance L21a and the distance L21b and the average of the distance L22. The same applies to the other switching elements 12 and 14. The power module 109 is specified so that the total distances are equal to each other.

The power module 109 enables to produce a similar effect to the effect of the power module 102.

### Eleventh Embodiment

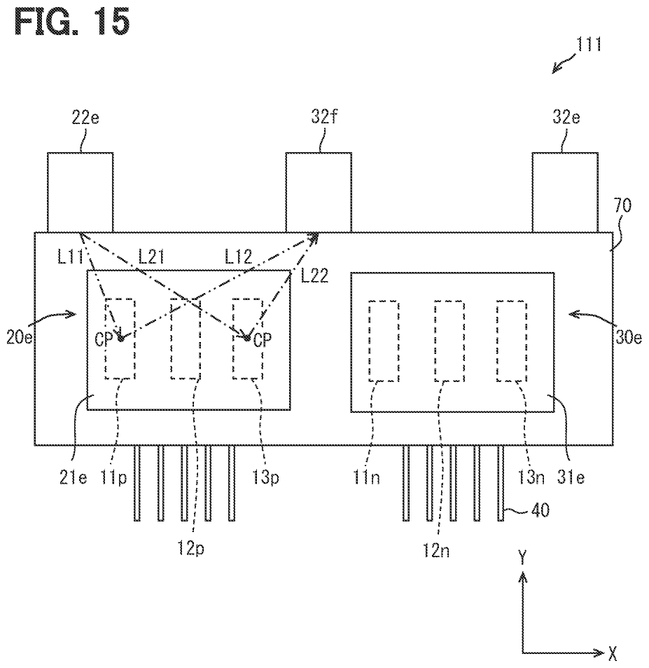

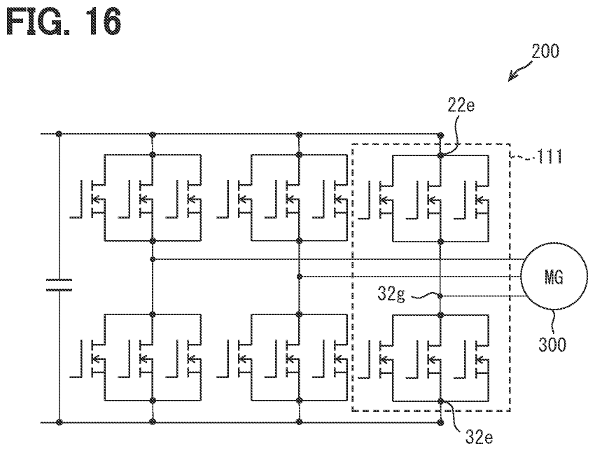

A power module 111 of the eleventh embodiment will be described with reference to FIGS. 15 and 16. Here, mainly, the configurations of the power module 111 different from the power module 101 will be described. The power module 111 differs from the power module 101 in that an upper arm and a lower arm are formed as one package. In the power module 111, the same components as those of the power module 101 are given the same reference numerals as those of the power module 101.

As shown in FIG. 15, the power module 111 includes, as switching elements of the upper arm, an upper arm first switching element 11p, an upper arm second switching element 12p, and an upper arm third switching element 13p. These switching elements 11p to 13p are connected in parallel with each other and are, in other words, upper arm elements.

Further, the power module 111 includes, as lower arm switching elements, a lower arm first switching element 11n, a lower arm second switching element 12n, and a lower arm third switching element 13n. These switching elements 11n to 13n are connected in parallel with each other and are, in other words, lower arm elements.

The power module 111 includes an upper arm terminal member 20e, a lower arm terminal member 30e, and an O terminal 32f. The upper arm terminal member 20e includes an upper arm heat sink 21e and a P terminal 22e. The lower arm terminal member 30e includes a lower arm heat sink 31e and an N terminal 32e.

As shown in FIG. 16, the power module 111 constitutes an upper arm and a lower arm of the inverter 200. The power module 111 includes the switching elements 11p to 13p, 11n to 13n, the upper arm terminal member 20e, the lower arm terminal member 30e, and the O terminal 32f in order to constitute the inverter 200. The power module 111 may also be applied to a converter.

The power module 110 enables to produce a similar effect to the effect of the power module 101.

Although the present disclosure has been described in accordance with the examples, it is understood that the present disclosure is not limited to such examples or structures. To the contrary, the present disclosure is intended to cover various modification and equivalent arrangements. In addition, while the various elements are shown in various combinations and configurations, which are exemplary, other combinations and configurations, including more, less or only a single element, are also within the spirit and scope of the present disclosure.

What is claimed is:

1. A power module comprising:
at least three switching elements that are connected in parallel with each other;
a positive electrode terminal that is connected to a positive electrode of each of the switching elements;
a negative electrode terminal that is connected to a negative electrode of each of the switching elements; and
a sealing portion that integrally seals the switching elements, a part of the positive electrode terminal, and a part of the negative electrode terminal, wherein
a total number of the positive electrode terminal and the negative electrode terminal is three or more,
a positive electrode side distance is a distance from a center of a switching element of the switching elements to the positive electrode terminal, which is closest to the switching element,
a negative electrode side distance is a distance from the center of the switching element to the negative electrode terminal, which is closest to the switching element, and
a total of the positive electrode side distance and the negative electrode side distance is equal for each of the switching elements.

2. The power module according to claim 1, wherein
the positive electrode terminal and the negative electrode terminal protrude from the sealing portion,
the positive electrode side distance is a distance between the center of the switching element and a boundary between the sealing portion and the positive electrode terminal, which is closest to the switching element, and
the negative electrode side distance is a distance between the center of the switching element and a boundary between the sealing portion and the negative electrode terminal, which is closest to the switching element.

3. The power module according to claim 2, wherein
the positive electrode side distance is a distance between the center of the switching element and a center of a boundary surface of the positive electrode terminal, which is closest to the switching element, at the boundary between the sealing portion and the positive electrode terminal, and
the negative electrode side distance is a distance between the center of the switching element and a center of a boundary surface of the negative electrode terminal, which is closest to the switching element, at the boundary between the sealing portion and the negative electrode terminal.

4. The power module according to claim 1, further comprising:
two or more gate terminals that are connected to gate electrodes of the switching elements, respectively, wherein
a gate distance that is a distance between the switching element and the gate terminal, which is closest to the switching element, is equal for each of the switching elements.

5. The power module according to claim 1, further comprising:
a signal terminal connected to the switching element, wherein
the signal terminal is provided on an opposite side of the positive electrode terminal and the negative electrode terminal with respect to the switching element.

6. The power module according to claim 1, wherein
the positive electrode terminal and the negative electrode terminal are arranged side by side in one direction, and
the switching elements include three or more of the switching elements that are arranged in a row along the one direction in which the positive electrode terminal and the negative electrode terminal are arranged.

7. The power module according to claim 1, wherein
the switching elements include three or more of the switching elements, and
at least one of the three or more switching elements is different from an other of the switching elements in element size.

8. The power module according to claim 1, wherein
each of the switching element is a semiconductor switching element,
the switching elements include three or more of the switching elements, and
at least one of the three or more switching elements is different from an other of the switching elements in semiconductor configuration.

9. A power module comprising:
at least three switching elements including a first switching element, a second switching element, and a third switching element that are connected in parallel with each other;
at least one positive electrode terminal that is connected to a positive electrode of each of the switching elements;
at least one negative electrode terminal that is connected to a negative electrode of each of the switching elements; and
a sealing portion that integrally seals the switching elements, a part of the positive electrode terminal, and a part of the negative electrode terminal, wherein
a total number of the positive electrode terminal and the negative electrode terminal is three or more,
a first positive electrode side distance is a distance from a center of the first switching element to the positive electrode terminal, which is closest to the first switching element,
a first negative electrode side distance is a distance from the center of the first switching element to the negative electrode terminal, which is closest to the first switching element, and
a second positive electrode side distance is a distance from a center of the second switching element to the positive electrode terminal, which is closest to the second switching element,
a second negative electrode side distance is a distance from the center of the second switching element to the negative electrode terminal, which is closest to the second switching element,
a third positive electrode side distance is a distance from a center of the third switching element to the positive electrode terminal, which is closest to the third switching element,
a third negative electrode side distance is a distance from the center of the third switching element to the negative electrode terminal, which is closest to the third switching element, and
a total of the first positive electrode side distance and the first negative electrode side distance, a total of the second positive electrode side distance and the second negative electrode side distance, and a total of the third positive electrode side distance and the third negative electrode side distance are equal to each other.
